(19) United States
(12) Patent Application Publication
(10) Pub. No.: US 2026/0271506 A1
(43) Pub. Date: Sep. 10, 2026

(54) LIGHT-EMITTING ELEMENT, DISPLAY DEVICE, METHOD FOR MANUFACTURING LIGHT-EMITTING ELEMENT, AND INORGANIC NANOPARTICLE DISPERSION LIQUID

(71) Applicant: Sharp Display Technology Corporation, Kameyama City, Mie (JP)

(72) Inventor: TAKAYUKI NAKA, Sakai City, Osaka (JP)

(21) Appl. No.: 19/164,715

(22) PCT Filed: Mar. 13, 2023
(86) PCT No.: PCT/JP2023/009510

§ 371 Date: Sep. 12, 2025

(51) Int. Cl. H10K 50/16; H10K 71/12

(52) U.S. Cl. CPC H10K 50/16; H10K 71/12

(57) ABSTRACT

A light-emitting element according to the disclosure has a light-emitting layer and a charge function layer layered between an anode and a cathode, the charge function layer contains inorganic nanoparticles and a first organic compound, and the first organic compound has a relative dielectric constant of 30 or more at 20° C.

### TECHNICAL FIELD

The disclosure relates to a light-emitting element, a display device, a method for manufacturing the light-emitting element, and an inorganic nanoparticle dispersion liquid.

### BACKGROUND ART

In recent years, various display devices provided with light-emitting elements have been developed, and in particular, a display device provided with quantum dot light-emitting diodes (QLEDs) or organic light-emitting diodes (OLEDs) has attracted a great deal of attention from perspectives such as the capability to achieve lower power consumption, a slimmer design, and higher picture qualities.

PTL 1 discloses an ink composition containing metal oxide nanoparticles, a binder, a solvent, an optional dispersant, and an optional surfactant. Further disclosed is a process of depositing the ink composition on a base material by using ink-jet printing or aerosol printing.

### CITATION LIST

### Patent Literature

PTL 1: JP 2020-097720 A

### SUMMARY OF INVENTION

### Technical Problem

In conventional QLEDs, since inorganic materials, particularly inorganic material nanoparticles, are used for a charge function layer in contact with an electrode, a solvent having high polarity is required for dissolving the inorganic materials or dispersing the inorganic material nanoparticles. For this reason, the solution is more likely to be repelled particularly on the partition walls, which can easily cause unevenness thereon. In addition, for example, when PTL 1 is adopted for forming a hole injection layer, there is a problem that the surfactant remains and the hole injection layer is peeled off by the solvent for the hole transport layer when the hole transport layer is to be formed. Therefore, because it is difficult to manufacture a light-emitting element in which the flatness of the charge function layers is maintained and the characteristics are stable, a new technique has been demanded.

In view of the above problems, an object of one aspect of the disclosure is to provide a light-emitting element having an inorganic nanoparticle layer with reduced unevenness, and a display device with improved uneven light emission and improved reliability.

### Solution to Problem

To solve the above-described problem, a light-emitting element according to an aspect of the disclosure includes an anode, a cathode, and a light-emitting layer and a charge function layer positioned between the anode and the cathode, the anode, the cathode, the light-emitting layer, and the charge function layer being layered. The charge function layer contains inorganic nanoparticles and a first organic compound, and the first organic compound has a relative dielectric constant of 30 or more at 20° C.

A display device according to an aspect of the disclosure includes a plurality of the light-emitting elements according to an aspect.

A method for manufacturing the light-emitting element according to an aspect of the disclosure includes applying an inorganic nanoparticle dispersion liquid containing the inorganic nanoparticles, and further the first organic compound and the second organic compound, onto one or both of the anode or the cathode and the light-emitting layer, and drying the inorganic nanoparticle dispersion liquid, forming a charge function layer containing the inorganic nanoparticles, in which the first organic compound has a higher relative dielectric constant than the second organic compound.

An inorganic nanoparticle dispersion liquid according to an aspect of the disclosure is used in the method for manufacturing the light-emitting element described above.

### Advantageous Effects of Invention

According to an aspect of the disclosure, a light-emitting element including an inorganic nanoparticle layer with reduced unevenness and a display device with improved uneven light emission and improved reliability can be realized.

### BRIEF DESCRIPTION OF DRAWINGS

FIG. 1 is a plan view illustrating a schematic configuration of a display device 100 according to an aspect of the disclosure.

FIG. 2 is a top view illustrating a schematic configuration of a light-emitting element 1 according to an aspect of the disclosure.

FIG. 3 is a cross-sectional view illustrating a schematic configuration of the light-emitting element 1 according to an aspect of the disclosure.

FIG. 4 is a view for schematically describing a shape of a bank 12 included in the light-emitting element 1 according to an aspect of the disclosure.

FIG. 5 is a view for schematically describing a film thickness distribution of a hole injection layer 20 included in the light-emitting element 1 according to an aspect of the disclosure.

FIG. 6 is a cross-sectional view illustrating a schematic configuration of a light-emitting element 1′ according to an aspect of the disclosure.

FIG. 7 is a view for schematically describing a film thickness distribution of an electron transport layer 26 included in the light-emitting element 1′ according to an aspect of the disclosure.

FIG. 8 is a diagram illustrating a schematic flow of an example of a method for manufacturing the light-emitting element 1 according to an aspect of the disclosure.

FIG. 9 is a diagram illustrating a schematic flow of an example of a method for manufacturing the light-emitting element 1′ according to an aspect of the disclosure.

### DESCRIPTION OF EMBODIMENTS

### Overview of Display Device

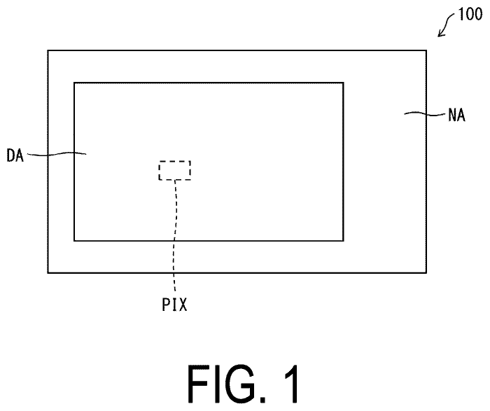

FIG. 1 is a plan view illustrating a schematic configuration of a display device 100 according to an aspect of the disclosure.

FIG. 1 is a view illustrating an example of a schematic configuration of the display device 100 according to an aspect of the disclosure. As illustrated in FIG. 1, the display device 100 according to the disclosure includes a display region DA in which display is performed by extracting light emitted from light-emitting elements 1 described below, and a frame region NA surrounding the display region DA. Although not illustrated, terminals T are formed in the frame region NA, the terminals receiving input of signals for driving light-emitting elements of the display device 100.

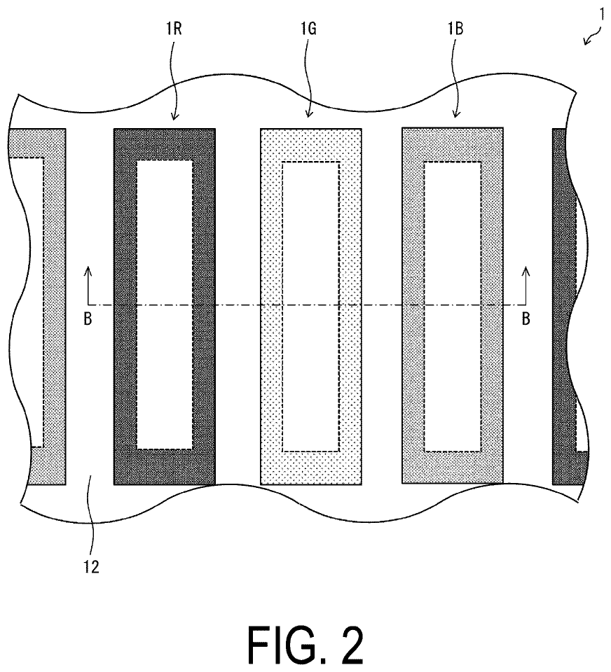

FIG. 2 is a plan view illustrating an example of a schematic configuration of the display region DA illustrated in FIG. 1. FIG. 2 corresponds to an enlarged top view of one pixel PIX illustrated in FIG. 1. Note that the light-emitting element 1 includes light-emitting elements 1R, 1G, and 1B surrounded by banks 12 as illustrated in FIG. 2, and each of the light-emitting elements 1R, 1G, and 1B may constitute subpixels in one pixel PIX illustrated in FIG. 1.

### Overview of Light-Emitting Element 1 (First Aspect)

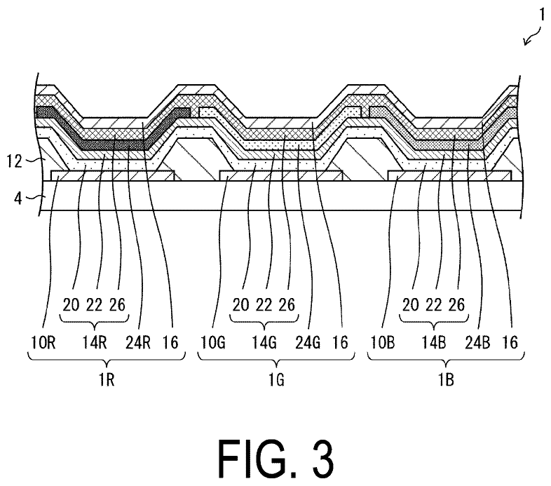

A configuration of the light-emitting element 1 according to the embodiment of the disclosure will be described with reference to FIG. 3. FIG. 3 is a cross-sectional view illustrating a schematic configuration of the light-emitting element 1 according to one aspect and corresponds to a cross-sectional view taken along the arrow line BB of FIG. 2.

The light-emitting element 1 according to one aspect includes a light-emitting element 1R, a light-emitting element 1G, and a light-emitting element 1B as a plurality of light-emitting elements, and the light-emitting elements 1R, 1G, and 1B are provided on a substrate 4 as illustrated in FIG. 3.

The light-emitting elements 1R, 1G, and 1B according to one aspect are provided between anodes 10R, 10G, and 10B formed on the substrate 4 and a cathode 16. Here, the light-emitting element 1R will be used for description among the light-emitting elements 1R, 1G, and 1B. The light-emitting element 1R includes a hole injection layer (HIL) 20, a hole transport layer (HTL) 22, and an electron transport layer (ETL) 26. In addition, a light-emitting layer 24R is provided between the hole transport layer 22 and the electron transport layer 26. Note that the hole injection layer 20, the hole transport layer 22, and the electron transport layer 26 may be referred to as a charge function layer 14R. The charge function layer refers to any one or all of the hole injection layer, the hole transport layer, and the electron transport layer. In addition, the charge function layer, for example, the light-emitting element 1R, may include an electron injection layer, which is not illustrated, between the electron transport layer 26 and the cathode 16. The electron injection layer may also be one of the layers included in the charge function layer. Like the light-emitting element 1R, the light-emitting elements 1G and 1B also include a charge function layer 14G and a charge function layer 14B, respectively, as charge function layers. Note that, unless otherwise specified in the disclosure, the light-emitting layer 24 refers to any one or all of the light-emitting layer 24R, the light-emitting layer 24G, and the light-emitting layer 24B, and the charge function layer 14 refers to any one or all of the charge function layer 14R, the charge function layer 14G, and the charge function layer 14B.

### Substrate

The substrate 4 includes a support substrate. The substrate 4 includes a thin film transistor layer (TFT layer) in which a circuit element such as a thin film transistor (TFT) is provided above the support substrate. The substrate 4 may further include additional components such as a barrier layer. The barrier layer reduces the amount of moisture, oxygen, and the like entering the light-emitting element 1 from the outside of the support substrate.

The support substrate may be a non-flexible substrate made of quartz, glass, or the like or a flexible substrate made of a resin film or a resin sheet. A quartz substrate and a glass substrate are preferable because they have high optical transparency and excellent gas shielding properties. Further, from the viewpoint of optical transparency and gas shielding properties, the material of the resin film is preferably a methacrylic resin represented by polyethylene methacrylate (PMMA), a polyester resin represented by polyethylene terephthalate (PET), polyethylene naphthalate (PEN), and polybutylene naphthalate (PBN), a polycarbonate resin, or the like.

### Anode and Cathode

The anodes 10 are provided on the substrate 4 in an island shape for each subpixel such that the light-emitting elements 1R, 1G, and 1B are separated individually, and are also referred to as “pixel electrodes”. The anode 10 includes the anode 10R for the light-emitting element 1R, the anode 10G for the light-emitting element 1G, and the anode 10B for the light-emitting element 1B. On the other hand, the hole injection layer 20, the hole transport layer 22, the electron transport layer 26, and the cathode 16 are each formed in common for the plurality of light-emitting elements. The cathode 16 is also referred to as a “common electrode”. Note that, unless otherwise specified in the disclosure, the anode 10 refers to any one or all of the anodes 10R, 10G, and 10B.

The anode 10 and the cathode 16 include an electrically conductive material and at least one is a transparent electrode. In a case in which the display device is a single-sided display, the electrode that is closer to the display surface from among the anode 10 and the cathode 16 is the transparent electrode, and the electrode farther from the display surface is a reflective electrode. In a case in which the display device is a double-sided display, both the anode 10 and the cathode 16 may be transparent electrodes. The transparent electrodes can be made of a conductive material with optical transparency. The reflective electrode can be made of conductive material with light reflectivity or can be made of a layered body including a conductive material with optical transparency and a conductive material with light reflectivity.

The conductive material with optical transparency includes indium tin oxide (ITO), indium zinc oxide (IZO), tin oxide (SnO₂), fluorine-doped tin oxide (FTO), and the like. Since these materials have a high transmittance with respect to visible light, the luminous efficiency of the light-emitting elements is improved. As the conductive material with light reflectivity, aluminum (Al), silver (Ag), copper (Cu), gold (Au), or the like can be used. Since these materials have a high reflectivity with respect to visible light, the luminous efficiency of the light-emitting elements is improved. Note that, when a conductive material with light reflectivity is thinly formed, the conductive material can be used as an optically transparent conductive material with optical transparency.

The anode 10 supplies holes to the light-emitting layer 24, and the cathode 16 supplies electrons to the light-emitting layer 24. The anode 10 can be provided facing the cathode 16.

### Bank (Partition Wall)

The banks 12 illustrated in FIG. 3 surround the anodes 10R, 10G, and 10G included in the light-emitting element 1. The banks 12 may be any banks that can separate the anodes 10R, 10G, and 10G provided on the substrate 4 in a top view to insulate the anodes from each other, and can be interpreted as insulators (insulating portions) of the anodes 10.

At least a part of the banks 12 may be disposed on any of the anodes 10, and any part of the banks 12 does not need to be disposed on the anodes 10. Specifically, a part of the banks 12 may be in contact with an end face of the anodes 10 and be used as pixel electrodes to isolate the anodes 10R, 10G, and 10B from each other in the light-emitting elements 1R, 1G, and 1B, and may not be disposed on the anodes 10R, 10G, and 10B. The banks 12 may be formed such that at least a part thereof overlaps the vicinities of the end faces of the anodes 10. The banks 12 are preferably formed so as to cover a portion near end faces (so-called “edges”) of the anodes 10. This electrically insulates the light-emitting element 1R, the light-emitting element 1G, and the light-emitting element 1B. Therefore, the banks 12 are also called “edge covers”.

It is advised that the banks 12 be an insulator formed of an insulating material, and may include, for example, resin materials such as polyimide resins, acrylic resins, novolac resins, and fluorene resins. The banks 12 can be formed by patterning a photosensitive resin composition that includes a photosensitizer such as a photo-radical generator or a photo-acid generator and a resin material, using, for example, a photolithography technique. The photosensitive resin composition may be a negative photosensitive resin composition or a positive photosensitive resin composition.

### Formation of Bank

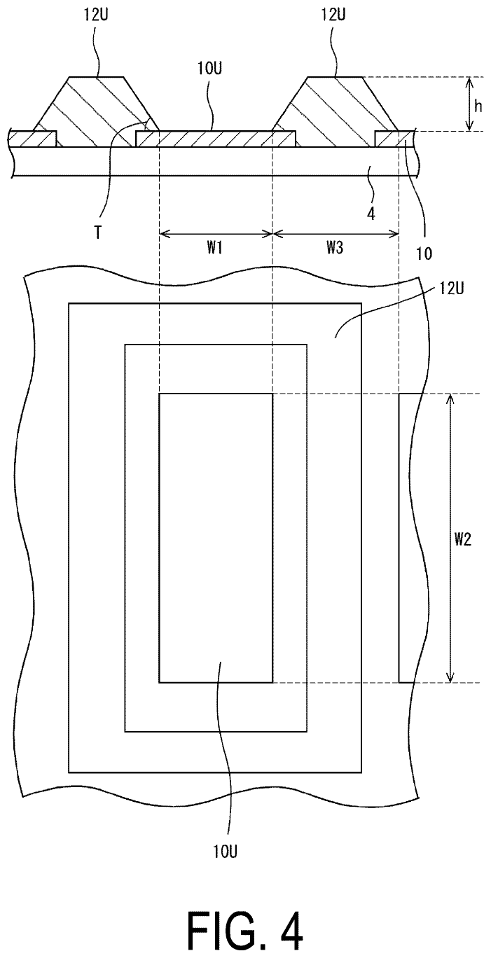

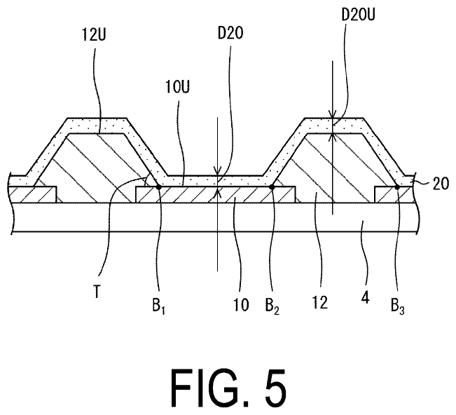

FIG. 4 is a diagram for describing an overview of the banks 12. Note that FIG. 4 illustrates a cross-sectional view of the banks 12 and a top view of a bank 12. The banks 12 surrounds an upper face portion 10U of the anode 10, thereby defining the shape of the outer periphery of the upper face portion (also the upper face) 10U as illustrated in FIG. 4. In addition, in the top view illustrated in FIG. 4, the bank 12 surrounds the upper face portion 10U of the anode 10 with the upper face portion 12U of the bank 12. The upper face portion 12U and the upper face portion 10U are surfaces on the side opposite to the substrate 4, and mean surfaces with which the hole injection layer 20 is in direct contact by applying an inorganic nanoparticle dispersion liquid for forming the hole injection layer 20 which is one of the charge function layers (FIG. 5).

Although a short-side width W1 of the upper face portion 10U of an anode 10 surrounded by the banks 12 is not limited, the short-side width is, for example, in a range of 5 μm to 100 μm, and preferably in a range of 5 μm to 50 μm. In addition, although a long-side width W2 of the upper face portion 10U surrounded by the banks 12 is not limited, the long-side width is, for example, in a range of 50 μm to 500 μm, and preferably in a range of 50 μm to 200 μm. Furthermore, a height h of each bank 12 in a plan view is preferably in a range of 0.1 μm to 2.0 μm. Each bank 12 preferably has an inclination angle T of greater than 0° and smaller than 45°, and more preferably greater than 0° and smaller than 30°. The upper face portion 10U of the anode 10 having a short-side width W1 in the range of 5 μm to 100 μm a width W2 in a range of 50 μm to 500 μm is surrounded by the bank 12 having a height h in the range of 0.1 μm to 2.0 μm, and a dispersion liquid containing inorganic nanoparticles, which will be described below, is used, and thereby the hole injection layer 20 and/or the electron transport layer 26 as charge function layers having an adjusted film thickness distribution as will be described below can be formed.

In addition, although a width W3 of an upper face portion 12U of the bank 12 is not limited, the width is, for example, in a range of 10 μm to 100 μm, and preferably in a range of 10 μm to 50 μm. Accordingly, even if, for example, the light-emitting layer 24R and the light-emitting layer 24G overlap each other and the light-emitting layer 24G and the light-emitting layer 24B overlap each other in the upper face portions 12U of the banks 12, it is possible to prevent the colors of the light-emitting layers from being mixed between the upper face portions 10U of the anodes 10 and the cathode 16 facing the upper face portions 10U. Note that the widths of the banks 12 at the portions intersecting the direction along the widths W3 of the upper face portions 12U may be within the same range as the widths W3 described above.

The upper face portions 10U of the anodes 10 illustrated in FIG. 4 may be formed at a density of about 1×10³ to 1×10⁵ pieces/cm² per unit area of the upper face of the substrate 4.

Note that, although the upper face portion 12U surrounds the anode 10U as a rectangular opening in the top view illustrated in FIG. 4, the shape of the upper face portion 12U in a top view is not limited thereto, and may be a circular shape or an elliptical shape, or may surround the anode 10U as an elliptical opening having two straight sides along the long-side width direction and having a radius in the short-side width direction.

### Hole Injection Layer

The hole injection layer 20 contains a material having hole transport properties and has a function of injecting holes from the anodes 10 to the hole transport layer 22 or the light-emitting layer 24. The hole transport layer 22 contains a material having hole transport properties and has a function of transporting holes from the hole injection layer 20 or the anodes 10 to the light-emitting layer 24. Note that, at least one of the hole injection layer 20 and the hole transport layer 22 preferably has a function of inhibiting the transport of electrons from the light-emitting layer 24 to the anodes 10.

The hole injection layer 20 contains inorganic nanoparticles as a material having a hole transport capability. Examples of inorganic nanoparticles may include one or more types selected from the group consisting of oxides, nitrides, and carbides containing one or more of Zn, Cr, Ni, Ti, Nb, Al, Si, Mg, Ta, Hf, Zr, Y, La, Sr, and W. Among these, oxides including one or more from among Zn, Cr, Ni, Ti, Nb, Al, Si, Mg, Ta, Hf, Zr, Y, La, and Sr are preferable, and at least one kind selected from NiO, MgO, MgNiO, LaNiO₃, CuO, and Cu₂O is more preferable. Furthermore, an example of a preferable hole transport material includes a material such as CuSCN in which a CN group, an SCN group, or a SeCN group is bonded to a metal.

The median diameter of the inorganic nanoparticles contained in the hole injection layer 20 is 0.5 to 100 nm, preferably 1 to 40 nm, and more preferably 1 to 10 nm. If the median diameter is within this range, the unevenness of the hole injection layer 20 is prevented from becoming large, and thus, an effect of preventing the generation of a reactive current that does not contribute to light emission between the hole injection layer 20 and the light-emitting layer or the hole transport layer (organic layer) is exhibited. It is advised to measure the median diameter as a particle size distribution based on volume by using a particle size distribution measurement device (e.g., Nanotrac wave II manufactured by MicrotracBEL Corp.).

The hole injection layer 20 contains inorganic nanoparticles having the hole transport capability and may further contain a first organic compound. The first organic compound means an organic solvent molecule in an organic solvent (first organic solvent) contained in an inorganic nanoparticle dispersion liquid used in the method for manufacturing a light-emitting element according to one aspect.

The first organic compound as an organic solvent has a relative dielectric constant of 30 or greater, and preferably 35 or greater at 20° C. In the light-emitting element 1 containing an organic solvent molecule having a relative dielectric constant of 30 or greater at 20° C. as the first organic compound, the film thickness distribution of the hole injection layer 20 is adjusted even if a surfactant is not substantially contained.

The first organic compound contained in the hole injection layer 20 may be any organic solvent having a boiling point of 150° C. or higher, and preferably 180° C. or higher. In addition, the boiling point of the first organic compound may be 300° C. or lower, and is more preferably 250° C. or lower. The first organic compound contained in the hole injection layer 20 has a boiling point of 150° C. or higher, and thus evaporation can be slowed down in the process of forming the hole injection layer 20. For this reason, the hole injection layer 20 containing the first organic compound having a boiling point of 150° C. or higher is formed so as to inhibit the dispersibility of the inorganic nanoparticles from being impaired. In addition, when the boiling point of the first organic compound contained in the hole injection layer 20 is 300° C. or lower, it is possible to prevent the first organic compound from remaining excessively in the process of forming the hole injection layer 20 and the hole injection layer 20 from being peeled.

The content of the first organic compound in the hole injection layer 20 may be 10 to 1000 ppm, and is more preferably 20 to 100 ppm. It is preferable for the content of the first organic compound in the hole injection layer 20 to be as small as possible in the range of 20 to 100 ppm from the viewpoint of enhancing the tolerability of the hole injection layer 20 to solvents and preventing peeling of the hole transport layer 22 to be described below, and to be as large as possible from the viewpoint that the first organic compound prevents inorganic nanoparticles from locally aggregating, which improves the flatness of the hole injection layer 20, prevents the generation of a reactive current described below, and thereby improving the reliability of the light-emitting element 1. Note that the hole injection layer 20 may be substantially free of the first organic compound by removing the first organic compound in the manufacturing process. The content of the first organic compound contained in the hole injection layer 20 can be quantitated by performing etching up to the hole injection layer 20 with gas cluster ion beam (GCIB) and by performing analysis using time-of-flight secondary ion mass spectrometry (TOF-SIMS) of the hole injection layer 20 and tandem mass spectrometry (MS/MS).

The hole injection layer 20 contains inorganic nanoparticles and may further contain a second organic compound. The second organic compound means an organic solvent molecule in an organic solvent (second organic solvent) contained in an inorganic nanoparticle dispersion liquid used in the method for manufacturing a light-emitting element according to one aspect. The second organic compound may have a lower relative dielectric constant than the first organic compound at 20° C., and the relative dielectric constant of the second organic compound at 20° C. is preferably less than 30.

In addition, the second organic compound may have a surface tension of 35 mN/m or less, and more preferably 30 mN/m or less. The second organic compound having a surface tension of 35 mN/m or less in the hole injection layer 20 can contribute to homogenization of the film thickness distribution of the hole injection layer 20 as will be described below.

That is, the hole injection layer 20 is formed from an inorganic nanoparticle dispersion liquid which contains inorganic nanoparticles and further contains the first organic compound and the second organic compound. Accordingly, the first organic compound contributes to the dispersibility of inorganic nanoparticles, which thus inhibits the aggregation of the inorganic nanoparticles even when no surfactant is contained, and the second organic compound contributes to the homogenization of the film thickness distribution of the hole injection layer 20 containing the inorganic nanoparticles. Accordingly, the hole injection layer 20 included in the light-emitting element 1 according to one aspect of the disclosure inhibits the aggregation of inorganic nanoparticles even without containing a surfactant and has homogeneous film thickness distribution in the upper face portions 10U of the anodes 10 and the upper face portions 12U of the banks 12. In addition, since the hole injection layer 20 contains no surfactant, the peeling of the hole injection layer 20 can be minimized.

Therefore, it is preferable that the hole injection layer 20 should not contain a surfactant. Here, the surfactant is a compound having interfacial properties since it has a hydrophilic group and a hydrophobic group, and examples thereof include an anionic surfactant, a cationic surfactant, an amphoteric surfactant, and a nonionic surfactant, and the surfactant contributes to the dispersibility, defoaming properties, and wettability of the inorganic nanoparticles, and contributes to the leveling properties of the dispersion liquid, and examples thereof include a dispersant, a defoaming agent, a wetting agent, a leveling agent, and an emulsifier.

The difference between the relative dielectric constant of the first organic compound at 20° C. and the relative dielectric constant of the second organic compound at 20° C. is preferably 10 or greater, and more preferably 20 or greater. This more suitably prevents the second organic compound from impairing the dispersibility of the inorganic nanoparticles contained in the hole injection layer 20 in the process of molding the hole injection layer 20.

In addition, the content of the second organic compound relative to the sum of the first organic compound and the second organic compound may be within the range of 10 mass % or greater and 50 mass % or less, and more preferably within the range of 20 mass % or greater and 35 mass % or less. This makes it possible to more suitably achieve homogenization of the film thickness distribution of the hole injection layer 20 while maintaining the dispersibility of the inorganic nanoparticles in the process of molding the hole injection layer 20.

In addition, when the difference in boiling point between the first organic compound and the second organic compound is 10° C. or less, the hole injection layer 20 can be formed without impairing the dispersibility attributable to the first organic compound and the homogenization of the film thickness attributable to the second organic compound in the process of molding the hole injection layer 20.

The content of the second organic compound in the hole injection layer 20 may be 10 to 100 ppm, and is more preferably 20 to 50 ppm. It is preferable for the content of the second organic compound in the hole injection layer 20 to be as small as possible within the range of 20 to 50 ppm from the viewpoint of increasing the tolerability of the hole injection layer 20 to solvents and preventing the peeling of the hole injection layer 20, and to be as large as possible from the viewpoint of more reliably achieving homogenization of the film thickness distribution of the hole injection layer 20 in the process of molding the hole injection layer 20. Note that the hole injection layer 20 may be substantially free of the second organic compound by removing the second organic compound in the manufacturing process. The content of the second organic compound contained in the hole injection layer 20 can be quantitated by performing etching up to the hole injection layer with gas cluster ion beam (GCIB) and by performing analysis using time-of-flight secondary ion mass spectrometry (TOF-SIMS) of the hole injection layer and tandem mass spectrometry (MS/MS).

Examples of the first organic compound that can be contained in the hole injection layer 20 include polyhydric alcohols such as ethylene glycol, propylene glycol, diethylene glycol, and glycerin; dimethyl sulfoxide (DMSO); amide organic solvents such as N,N-dimethylformamide (DMF), formamide (FA), N-methylformamide (MFA), N-methylacetamide, N,N-dimethylacetamide, and N-methyl-2-pyrrolidone (NMP).

Examples of the second organic compound that can be contained in the hole injection layer 20 include aliphatic alcohol solvents such as 1-octanol, 1-heptanol, 1-hexanol, and cyclohexanol; aliphatic ketone solvents such as cyclohexanone, 2-undecanone, and 2-heptanone; and aliphatic hydrocarbon solvents such as dodecane and decane.

### Film Thickness Distribution of Hole Injection Layer

The hole injection layer 20 may have a difference between the mean value of the film thickness distribution of a film thickness D20 and the mean value of the film thickness distribution of D20U of not more than the 50 nm as illustrated in FIG. 5, and the film thickness D20 and the film thickness D20U of the hole injection layer 20 are defined as follows.
1) Film thickness D20 of a portion in contact with the hole transport layer 22 and the anode 10
2) Film thickness D20U of the portion in contact with the hole transport layer 22 and the bank 12

The film thicknesses D20 and D20U refer to the thicknesses of the hole transport layer 22 along the normal direction of the upper face portion 10U of the anode 10 and the upper face portion 12U of the bank 12 as illustrated in FIG. 5. Note that, when the upper face portion (upper face) 12U of the bank 12 is formed of a non-flat inclined face and a top face, a flat imaginary face close to each of the inclined face and the top face may be designed for each of the inclined face and the top face, and the thickness along the normal direction of the imaginary face may be adopted. The film thickness D20 and the film thickness D20U can be obtained as mean values obtained by measuring the respective thicknesses a plurality of times through electron microscopic observation. For example, the light-emitting element 1 may be cut out along the arrow line BB illustrated in FIG. 2, perpendicular to the upper face portion 10U of the anode 10, and the thickness of the upper face portion 10U and the thickness of the hole injection layer 20 in contact with the upper face portion 10U may be measured at a plurality of positions in the obtained cross section. More specifically, the film thickness distribution of the hole injection layer 20 in contact with the upper face portion 10U illustrated in FIG. 5 may be calculated by measuring thicknesses at a plurality of positions (measurement points) spaced apart at equal intervals at the inner side of boundary points B₁ and B₂ between the upper face portion 10U and the upper face portion 12U, which are located at both ends of the upper face portion 10U of the anode 10, as the mean value of the film thicknesses obtained at the plurality of positions. Similarly, the thicknesses of the upper face portion 12U of the bank 12 may be measured at a plurality of positions spaced apart from each other at equal intervals at the inner side of the boundary points B₂ and B₃ located at both ends of the upper face portion, and the mean value of the obtained film thicknesses may be calculated as the mean value of the film thickness distribution.

The difference between the mean value of the film thickness distribution at the thickness D20 of the hole injection layer 20 and the mean value of the film thickness distribution at D20U may be equal to or less than 50 nm. By making the difference in the mean value of the film thickness distribution smaller than 50 nm, the easy occurrence of uneven light emission in the hole transport layer 22 and the light-emitting layer 24, which are the upper layers, can be prevented. In the hole injection layer 20 in contact with the upper face portions 10U of the anodes 10 and the upper face portions 12U of the banks 12 illustrated in FIG. 5, the thickness D20 may be 10 nm or greater at the thinnest portion, or may be 150 nm or less at the thicker portion. This is because, when the film thickness D20 is thinner than 10 nm, the hole transport property of the hole injection layer 20 may be impaired. In addition, when the film thickness D20 is thicker than 150 nm, a crack may occur in the hole injection layer 20 in the manufacturing stage. Such cracks may reduce the efficiency of hole injection from the hole injection layer 20 to the hole transport layer 22.

The hole injection layer 20 may have a self-assembled monolayer (SAM) on the surface. The SAM decreases the driving voltage of the light-emitting element.

The hole injection layer 20 preferably has a physical property that inhibits “peeling”. Specifically, the hole injection layer 20 preferably has a film thickness reduction rate of 10% or lower after the hole injection layer 20 is formed on a glass substrate provided with the anodes 10 and the banks 12 and then immersed in chlorobenzene for 24 hours. This increases the tolerability of the hole injection layer 20 against solvents with a composition for forming the hole transport layer 22 or the light-emitting layer 24 that will be formed in the later steps. In the hole injection layer 20, the first organic compound and the second organic compound are substantially free of a surfactant, and thus the film thickness reduction rate of the hole injection layer 20 can be 10% or less.

The hole injection layer 20 is formed on the upper face portion 10U and the upper face portions 12U of the banks 12 as a flat hole injection layer 20 in which (i) generation of unevenness attributable to aggregation of inorganic nanoparticles is curbed and (ii) coating unevenness is reduced on the upper face portions 10U of the anodes 10 and the upper face portion 12U of the banks 12, which are made of materials having different polarities, by using the first organic compound and the second organic compound in the manufacturing process. Therefore, (i) the generation of a reactive current that does not contribute to the light emission of the light-emitting layer 24 can be reduced. (ii) Since the hole injection layer 20 has reduced unevenness on the surface and is formed to be flat without unevenness regardless of the difference in the materials of the upper face portion 10U and the upper face portion 12U, the hole transport layer 22 and/or the light-emitting layer 24 are formed to be flat on the hole injection layer 20 without unevenness. Therefore, in the light-emitting element 1, the light-emitting layer 24 is formed with high positional accuracy by coming in contact with the upper face portions 10U of the anodes 10 and the upper face portion 12U of the banks 12.

### Hole Transport Layer (Organic Layer)

The hole transport layer 22 is also referred to as an organic layer. The hole transport layer 22, for example, preferably includes an organic hole transport material having an electrical resistivity higher than that of polyethylenedioxythiophene doped with polystyrene sulfonic acid (PEDOT:PSS). This brings higher luminance and external quantum efficiency (EQE) to the light-emitting element 1. Preferred organic hole transport materials can be appropriately selected from materials that are generally used in that field, and examples thereof include, for example, 4,4′,4″-tris(9-carbazolyl)triphenylamine (TCTA), 4,4′-bis[N-(1-naphthyl)-N-phenyl-amino]-biphenyl (NPB), zinc phthalocyanine (ZnPC), di[4-(N,N-ditolylamino)phenyl]cyclohexane (TAPC), 4,4′-bis(carbazol-9-yl) biphenyl (CBP), 2,3,6,7, materials such as 10,11-hexacyano-1,4,5,8,9,12-hexaazatriphenylene (HATCN), poly(N-vinylcarbazole) (PVK), poly(2,7-(9,9-di-n-octylfluorene)-(1,4-phenylene-((4-sec-butylphenyl)imino)-1,4-phenylene (TFB), and poly(triphenylamine) derivatives (Poly-TPD). Among these, a tetracyano compound such as TFB, a carbazole derivative such as PVK, and a triarylamine derivative such as Poly-TPD are preferable.

In the upper face portions 10U of the anodes 10 and the upper face portions 12U of the banks 12, the thickness of the hole transport layer 22 is preferably 10 nm or greater at the thinnest portion, or 100 nm or less at the thickest portion. The reason for this is that the hole transport properties of the hole transport layer 22 are more likely to be impaired when the thickness is thicker than 10 nm. In addition, this is because, when the thickness is thicker than 100 nm, the driving voltage of the light-emitting element may increase.

### Light-Emitting Layer

The light-emitting layer 24 includes a light-emitting layer 24R that emits red light, a light-emitting layer 24G that emits green light, and a light-emitting layer 24B that emits blue light. In the disclosure, “blue light” refers to, for example, light having a light emission central wavelength in a wavelength band from 400 nm to 500 nm. Also, “green light” refers to, for example, light having a light emission central wavelength in a wavelength band from greater than 500 nm to 600 nm. Also, “red light” refers to, for example, light having a light emission central wavelength in a wavelength band from greater than 600 nm to 780 nm.

The light-emitting layer 24 is a layer that emits light when recombination of holes from the anode 10 and electrons from the cathode 16 causes luminescent bodies to excite and then the luminescent bodies return to a ground state. When a voltage between the anode 10 and the cathode 16 or a current is applied, recombination occurs in the light-emitting layer 24 and light is emitted. The light-emitting layer 24 may include quantum dots or an organic light-emitting material as the luminescent bodies.

A quantum dot is a dot having a maximum width of 100 nm or less. The shape of the quantum dot is not particularly limited as long as it is within a range satisfying the maximum width, and the shape is not limited to a spherical three-dimensional shape (circular cross-sectional shape). The shape of the quantum dot 17 may be, for example, a polygonal cross-sectional shape, a rod-shaped three-dimensional shape, a branch-shaped three-dimensional shape, or a three-dimensional shape having unevenness on the surface thereof, or a combination of them. Quantum dots in the disclosure, for example, are semiconductor fine particles having a particle size equal to or less than 100 nm, and can include a group II-VI semiconductor compound such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe, and/or a crystal of a group III-V semiconductor compound such as GaAs, GaP, InN, InAs, InP, and InSb, and/or a crystal of a group IV semiconductor compound such as Si and Ge. Furthermore, quantum dots may have, for example, a core/shell structure in which the semiconductor crystal described above is a core and a shell material having a high band gap is coated over the core. Furthermore, the quantum dot may include a ligand adsorbed (coordinated) on the surface of the quantum dot. Note that the shell is not necessarily required to completely cover the core, and may be formed so as to cover a portion of the core. Since quantum dots and a compound for forming the ligand are included in the light-emitting layer 24, the compound can be considered a ligand adsorbed (coordinated) on the surface of the quantum dots.

The light-emitting layer 24 is formed to cover the upper face portions 10U of the anodes 10 exposed at least from the upper face portions 12U of the banks 12 when the light-emitting element 1 is viewed from the top face. When the hole transport layer 22 and the electron transport layer 26 come into contact with one another above or in the vicinity above the exposed region of the anode 10, a reactive current that does not contribute to light emission of the light-emitting layer 24 flows through the contact site. For this reason, the light-emitting layer 24 preferably covers the upper face portions 10U of the anodes 10 and a part of the upper face portion 12U of the banks 12 surrounding the upper face portions 10U (in particular, a part of the upper face portions 12U having the largest height h). In addition, since the light-emitting layer 24 covers the upper face portions 12U of the banks 12 over a wide range as illustrated in FIG. 3, the reactive current can be further reduced. To be more specific, for example, the light-emitting layer 24 covers the vicinity of the portion of the upper face portions 12U of the banks 12 where the height h is the largest with high positional accuracy, and thereby the reactive current can be further reduced. This can enhance the reliability of the light-emitting element 1 and further the display device 100.

### Electron Transport Layer

The electron transport layer 26 includes a material having electron transport properties and has a function of transporting electrons from the cathode 16 to the light-emitting layer 24. The electron transport layer 26 preferably has a function of inhibiting the transport of positive holes from the light-emitting layer 24 to the cathode 16.

Examples of an organic electron transport material suitable for the electron transport layer 26 include compounds and complexes including one or more nitrogen-containing heterocycles such as oxadiazole ring, triazole ring, triazine ring, quinoline ring, phenanthroline ring, pyrimidine ring, pyridine ring, imidazole ring, and carbazole ring. Specific examples include 1,10-phenanthroline derivatives such as bathocuproine and bathophenanthroline; benzimidazole derivatives such as 1,3,5-tris(N-phenylbenzimidazol-2-yl)benzene (TPBI); metal complexes such as (tris(8-quinolinato)aluminum) complex (Alq3), bis(10-benzoquinolinolato)beryllium complex, 8-hydroxyquinoline Al complex, bis(2-methyl-8-quinolinato)-4-phenylphenolate aluminum; and 4,4′-bis(carbazole)biphenyl. Other examples thereof include aromatic boron compounds, aromatic silane compounds, aromatic phosphine compounds such as phenyldi(1-pyrenyl)phosphine, bathophenanthroline, bathocuproine, 2,2′,2″-(1,3,5-benzenetriyl)-tris(1-phenyl-1-H-benzimidazole) (TPBI), nitrogen-including heterocyclic compounds such as triazine derivatives.

Another example of an organic electron transport material suitable for the electron transport layer 26 includes a compound having a paraphenylene vinylene backbone, for example. Specific examples include polyparaphenylene vinylene (PPV) compounds such as poly(2-2′-ethyl-hexoxy)-5-methoxy-1,4-phenylene vinylene (POPh-PPV).

In addition, the inorganic electron transport material suitable for the electron transport layer 26 is the same as the inorganic nanoparticles contained in the electron transport layer 26 included in the light-emitting element 1′ described later, and thus the description thereof will be omitted.

### Light-Emitting Element 1′

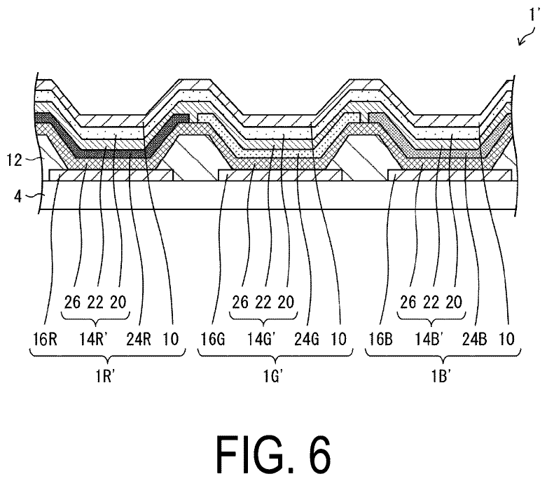

The light-emitting element according to an aspect of the disclosure is not limited to the aspect (first aspect) described above. As illustrated in FIG. 6, the light-emitting element 1′ according to an aspect of the disclosure includes light-emitting elements 1R′, 1G′, and 1B′ as a plurality of light-emitting elements. Each of the light-emitting elements 1R′, 1G′, and 1B′ includes, between any one of cathodes 16R, 16G, and 16B and an anode 10, an electron transport layer 26, any one of light-emitting layers 24R, 24G, and 24B, a hole transport layer 22, and a hole injection layer 20 in this order from the substrate 4 side, and here, a charge function layer 14′ includes an electron transport layer (ETL) 26, a hole transport layer (HTL) 22, and a hole injection layer (HIL) 20, and a light-emitting layer 24 is stacked between the electron transport layer 26 and the hole transport layer 22. In addition, the light-emitting element 1R′ may include, as a charge function layer, an electron injection layer, which is not illustrated, between the electron transport layer 26 and the cathode 16. The electron injection layer may also be one of the layers included in the charge function layer. Note that, unless otherwise specified in the disclosure, the charge function layer 14′ refers to any or all of a charge function layer 14R′, a charge function layer 14G′, and a charge function layer 14B′ for convenience.

The cathodes 16R, 16G, and 16B are individually formed for each of the light-emitting elements, and are also referred to as “pixel electrodes”. On the other hand, each of the hole injection layer 20, the hole transport layer 22, the electron transport layer 26, and the cathodes 16 is formed in common for the plurality of light-emitting elements 1R in the light-emitting element 1′. The anode 10 is also referred to as a “common electrode”. In the light-emitting element 1′ according to an aspect of the disclosure, the cathode 16 may refer to any or all of the cathodes 16R, 16G, and 16B for convenience.

That is, whereas the light-emitting element 1 is a light-emitting element with a sequential layered structure in which the anodes 10, the hole injection layer 20, the hole transport layer 22, the light-emitting layer 24, the electron transport layer 26, and the cathode 16 are stacked in this order from the substrate 4 side, the light-emitting elements 1R′, 1G′, and 1B′ included in the light-emitting element 1′ are light-emitting element with an inverse layered structure in which the cathodes 16, the electron transport layer 26, the light-emitting layer 24, the hole transport layer 22, and the hole injection layer 20 are stacked in this order from the substrate 4 side.

### Electron Transport Layer

The electron transport layer 26 of the light-emitting element 1′ contains inorganic nanoparticles as a material having an electron transport capability. An example of inorganic nanoparticles includes an oxide containing one or more of Zn, Ni, Cr, Mg, Li, Ti, W, Mo, In, and Ga. Among these, an oxide that tends to shift to the oxygen deficiency side based on the stoichiometric composition is preferable. Examples thereof include zinc oxide (ZnO), magnesium zinc oxide (MgZnO), titanium oxide (TiO₂), strontium oxide (SrTiO₃), and the like.

The electron transport layer 26 of the light-emitting element 1′ contains inorganic nanoparticles and may further contain a first organic compound, and examples thereof include the same compound as the first organic compound described above. In the light-emitting element 1′ containing an organic solvent molecule having a relative dielectric constant of 30 or greater at 20° C. as the first organic compound, the film thickness distribution of the electron transport layer 26 is adjusted even if a surfactant is not substantially contained.

The content of the first organic compound in the electron transport layer 26 may be 10 to 1000 ppm, and is more preferably 20 to 100 ppm. It is preferable for the content of the first organic compound in the electron transport layer 26 to be as small as possible in the range of 20 to 100 ppm from the viewpoint of enhancing the tolerability of the hole injection layer 20 to solvents and preventing peeling of the light-emitting layer 24, and to be as large as possible from the viewpoint that the first organic compound prevents inorganic nanoparticles from locally aggregating, which improves the flatness of the electron transport layer 26, prevents the generation of a reactive current described below, and thereby improving the reliability of the light-emitting element 1. Note that the electron transport layer 26 may be substantially free of the first organic compound by removing the first organic compound in the manufacturing process. The content of the first organic compound contained in the electron transport layer 26 can be quantitated by performing etching up to the hole injection layer with gas cluster ion beam (GCIB) and by performing analysis using time-of-flight secondary ion mass spectrometry (TOF-SIMS) of the hole injection layer and tandem mass spectrometry (MS/MS).

The electron transport layer 26 of the light-emitting element 1′ contains inorganic nanoparticles and may further contain a second organic compound, and examples thereof include the same compound as the second organic compound described above. The second organic compound having surface tensions of 35 mN/m or less in the electron transport layer 26 contributes to homogenization of the film thickness distribution of the electron transport layer 26 as will be described below.

That is, the electron transport layer 26 of the light-emitting element 1′ is formed from an inorganic nanoparticle dispersion liquid, which contains inorganic nanoparticles having an electron transport capability and further contains the first organic compound and the second organic compound. Accordingly, the first organic compound contributes to the dispersibility of inorganic nanoparticles, which thus inhibits the aggregation of the inorganic nanoparticles even when no surfactant is contained, and the second organic compound contributes to the homogenization of the film thickness distribution of the electron transport layer 26 containing the inorganic nanoparticles. Accordingly, the electron transport layer 26 included in the light-emitting element 1 according to one aspect of the disclosure inhibits the aggregation of inorganic nanoparticles even without containing a surfactant and has a homogenized film thickness distribution in the upper face portions 16U of the cathodes 16 and the upper face portions 12U.

The difference between the relative dielectric constant of the first organic compound at 20° C. and the relative dielectric constant of the second organic compound at 20° C. is preferably 10 or greater, and in the process of molding the electron transport layer 26, the dispersibility of the inorganic nanoparticles contained in the electron transport layer 26 is more suitably prevented from being impaired by the second organic compound.

In addition, the content of the second organic compound relative to the sum of the first organic compound and the second organic compound may be within the range of 10 mass % or more and 50 mass % or less, and the homogenization of the film thickness distribution of the electron transport layer 26 can be more preferably achieved in the process of molding the electron transport layer 26.

In addition, if the difference in boiling point between the first organic compound and the second organic compound is 10° C. or less, the electron transport layer 26 can be formed without impairing the dispersibility of the first organic compound and the homogenization of the film thickness of the second organic compound in the process of molding the electron transport layer 26.

The content of the second organic compound in the electron transport layer 26 may be 10 to 100 ppm, and is more preferably 20 to 50 ppm. It is preferable for the content of the second organic compound in the hole injection layer 20 to be as small as possible within the range of 20 to 50 ppm from the viewpoint of increasing the tolerability of the electron transport layer 26 to solvents and preventing the peeling of the light-emitting layer 24, and to be as large as possible from the viewpoint of more reliably achieving homogenization of the film thickness distribution of the electron transport layer 26 in the process of molding the electron transport layer 26. Note that the electron transport layer 26 may be substantially free of the second organic compound by removing the second organic compound in the manufacturing process. The content of the second organic compound contained in the electron transport layer 26 can be quantitated by performing etching up to the hole injection layer with gas cluster ion beam (GCIB) and by performing analysis using time-of-flight secondary ion mass spectrometry (TOF-SIMS) of the hole injection layer and tandem mass spectrometry (MS/MS).

Specific examples of the first organic compound and the second organic compound that can be contained in the electron transport layer 26 of the light-emitting element 1′ are the same as the examples of the first organic compound and the second organic compound that can be contained in the hole injection layer 20 of the light-emitting element 1, and therefore, the description thereof is omitted.

The electron transport layer 26 preferably has physical properties that inhibit “peeling”. Specifically, the electron transport layer 26 preferably has a film thickness reduction rate of 10% or lower after the electron transport layer 26 is formed on a glass substrate provided with the cathodes 16 and the banks 12 and then immersed in chlorobenzene for 24 hours. Accordingly, the electron transport layer 26 has enhanced solvent tolerability against the composition for forming the light-emitting layer formed in later steps. In the electron transport layer 26, the first organic compound and the second organic compound are substantially free of a surfactant, and thus the film thickness reduction rate of the electron transport layer 26 can be 10% or less. Here, the surfactant is the same as the above-described surfactant, and thus the description thereof will be omitted.

### Film Thickness Distribution of Electron Transport Layer

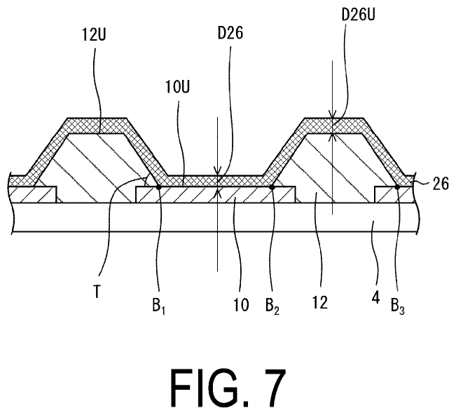

As illustrated in FIG. 7, in the electron transport layer 26 of the light-emitting element 1′, the difference between the mean value of the film thickness distribution in a film thickness D26 and the mean value of the film thickness distribution in D26U, which are described below, may be 50 nm or less, and the film thickness D26 and the film thickness D26U of the electron transport layer 26 are defined as follows.
1) Film thickness D26 of the portion at which the electron transport layer 26 is in contact with the cathode 16
2) Film thickness D26U of the portion at which the electron transport layer 26 is in contact with the bank 12

The film thicknesses D26 and D26U refer to the thicknesses of the electron transport layer 26 along the normal direction of the upper face portion 16U of the cathode 16 and the upper face portion 12U of the bank 12, respectively, illustrated in FIG. 7. Note that, when the upper face portion (upper face) 12U of the bank 12 is formed of a non-flat inclined face and a top face, a flat imaginary face close to each of the inclined face and the top face may be designed for each of the inclined face and the top face, and the thickness along the normal direction of the imaginary face may be adopted for measurement of the film thickness D26 and the film thickness D26U. Each of the film thickness D26 and the film thickness D26U can be obtained as mean values obtained by measuring the respective thicknesses a plurality of times through electron microscopic observation. The procedures of measuring the film thickness D26 and the film thickness D26U illustrated in FIG. 7 are the same as the above-described procedures of measuring the film thickness D20 and the film thickness D20U, and thus the description thereof will be omitted.

The difference between the mean value of the film thickness distribution of the film thickness D26 of the electron transport layer 26 and the mean value of the film thickness distribution of D26U is 50 nm or less, and in the upper face portion 16U of the cathode 16 and the upper face portion 12U of the bank 12 illustrated in FIG. 7, the difference may be 10 nm or greater at the thinnest portion, or may be 150 nm or less at the thickest portion. The reason for this is that the electron transport properties of the electron transport layer 26 are more likely to be impaired when the thickness is thinner than 10 nm. In addition, when the thickness is larger than 150 nm, a crack may occur in the electron transport layer 26 in the manufacturing stage. Such cracks may reduce the efficiency of electron transport from the electron transport layer 26 to the light-emitting layer 24.

### Hole Injection Layer

The hole injection layer 20 included in the light-emitting element 1′ may contain an inorganic hole transport material or an organic hole transport material. The inorganic hole transport material is preferably a metal oxide, and in this case, the chemical stability is further increased.

Examples of the inorganic hole transport material suitable for the hole injection layer 20 included in the light-emitting element 1′ include a material including one or more types selected from the group consisting of oxides, nitrides, and carbides containing one or more of Zn, Cr, Ni, Ti, Nb, Al, Si, Mg, Ta, Hf, Zr, Y, La, Sr, and W. Among these, oxides including one or more from among Zn, Cr, Ni, Ti, Nb, Al, Si, Mg, Ta, Hf, Zr, Y, La, and Sr are preferable, and at least one kind selected from NiO, MgO, MgNiO, LaNiO₃, CuO, and Cu₂O is more preferable. Furthermore, an example of a preferable hole transport material includes a material such as CuSCN in which a CN group, an SCN group, or a SeCN group is bonded to a metal. These materials may be nanoparticles.

Examples of the organic hole transport material suitable for the hole injection layer 20 included in the light-emitting element 1′ include materials such as 4,4′,4″-tris(9-carbazoyl)triphenylamine (TCTA), 4,4′-bis[N-(1-naphthyl)-N-phenyl-amino]-biphenyl (NPB), zinc phthalocyanine (ZnPC), di[4-(N,N-ditolylamino)phenyl]cyclohexane (TAPC), 4,4′-bis(carbazol-9-yl)biphenyl (CBP), 2,3,6,7,10,11-hexacyano-1,4,5,8,9,12-hexaazatriphenylene (HATCN), (3,4-ethylenedioxythiophene):poly(4-styrenesulfonic acid) (PEDOT:PSS), and the like.

### Method for Manufacturing Light-Emitting Element 1

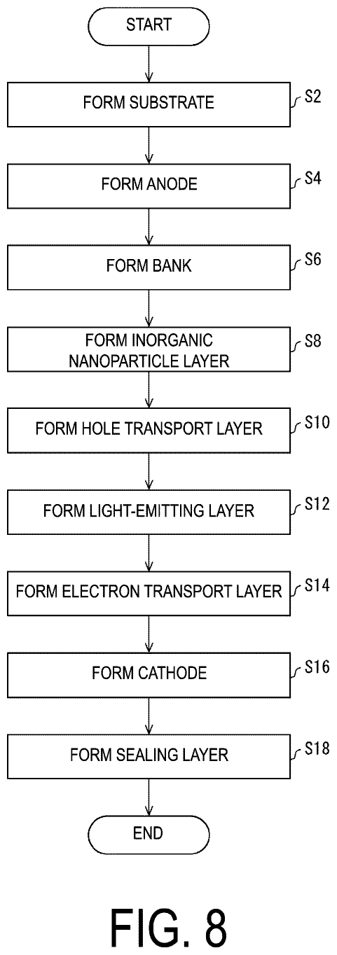

FIG. 8 illustrates a schematic flow of an example of a method for manufacturing the light-emitting element 1 according to an aspect of the disclosure.

In the method for manufacturing the light-emitting element 1, first, the substrate 4 is formed (step S2). The substrate 4 may be formed by, for example, forming, on a rigid glass substrate, a film base material and TFTs on the film base material, and then peeling the glass substrate from the film base material. The peeling of the glass substrate described above may be executed after formation of the light-emitting element 2 and a sealing layer described below. Alternatively, the substrate 4 may be formed by, for example, forming the TFTs directly on a rigid glass substrate.

Next, the anode 10 is formed on the substrate 4 (step S4). The anode 10 may be formed by, for example, forming a thin film of a metal material by a sputtering method, a vacuum vapor deposition technique, or the like, and then patterning the thin film by dry etching or wet etching using a photoresist. Thus, the anode 10R, the anode 10G, and the anode 10B formed into island shapes on a subpixel-by-subpixel basis on the substrate 4 are obtained.

Next, the banks 12 are formed (step S6). In step S6, the banks 12 are formed by photolithography using a positive photosensitive resin composition. Specifically, for example, a positive photosensitive resin composition serving as the material of the banks 12 is applied to the face of the substrate 4 on which the anode 10 has been formed. Next, a photomask having a light-transmitting portion at a position corresponding to each subpixel is placed above the photosensitive resin composition that has been pre-baked after the application, and the photosensitive resin is irradiated with ultraviolet light or the like through the photomask. Subsequently, the photosensitive resin irradiated with ultraviolet light may be washed with a suitable developing solution. Thereby, the banks 12 can be formed between the positions corresponding to the subpixels on the substrate 4. Note that the height h of the banks 12 may be adjusted by the amount of the photosensitive resin composition applied.

In general, as a distance between the photomask and an exposure target increases, an exposure area and an exposure intensity of the photomask in a plan view tend to decrease. For this reason, when the banks 12 are formed by photolithography using a positive photosensitive resin composition, the banks 12 are narrowed gradually upwardly from the substrate 4 side. Accordingly, in step S6, the banks 12 are formed by applying, exposing, and developing the positive photosensitive resin composition, making it possible to form the banks 12 having the inclined face in a forwardly tapered shape.

Next, the hole injection layer 20, that is, an inorganic nanoparticle layer that is a hole-injecting material is formed (step S8). The hole injection layer 20 may be formed by, for example, applying an inorganic nanoparticle dispersion liquid by an ink-jet method or an aerosol jet method and drying the applied dispersion by heating or vacuum drying.

The median diameter of the inorganic nanoparticles is 0.5 to 100 nm, preferably 1 to 40 nm, and more preferably 1 to 10 nm. As a method for measuring a particle size, for example, a method of measuring a particle size distribution using a particle size distribution measurement device (e.g., Nanotrac wave II, manufactured by MicrotracBEL Corp.) and using the obtained result as a particle size.

The inorganic nanoparticle dispersion liquid preferably has physical properties suitable for coating described below. In addition, the inorganic nanoparticle dispersion liquid contains a first organic solvent as a first organic compound to be described below, and may further contain a second organic solvent as a second organic compound to be described below. This provides good wettability of the anode 10 and the banks 12.

The first organic solvent is preferably an organic solvent having a relative dielectric constant of 30 or more at 20° C., and is preferably selected according to the dispersibility of the inorganic nanoparticles to be dispersed. The second organic solvent is preferably selected from organic solvents having a relative dielectric constant of less than 30 at 20° C. so that the dispersibility of the inorganic nanoparticles to be dispersed is not excessively impaired.

In addition, the second organic solvent as the second organic compound may have a surface tension of 35 mN/m or less at 20° C., and more preferably 30 mN/m or less. The second organic solvent having a surface tension of 35 mN/m or less can increase the wettability with respect to the upper face portions 12U of the banks 12, which is made of a different material from the anode 10, and thus can increase the flatness of the film thickness distribution of the hole injection layer 20.

In order % to maintain the dispersibility of the inorganic nanoparticles, the content of the second organic solvent in the inorganic nanoparticle dispersion liquid is preferably adjusted to 10 wt. % or more and less than 50 wt. % in the total content of the first organic solvent as the first organic compound and the second organic solvent as the second organic compound. In the inorganic nanoparticle dispersion liquid, (i) the dispersibility of the inorganic nanoparticles and the wettability with respect to the upper face portion 10U of the anode 10 can be enhanced by increasing the content of the first organic solvent in the range of 50 wt. % or more and less than 90 wt. %, (ii) the wettability with respect to the upper face portions 12U of the banks 12 can be enhanced by increasing the content of the second organic solvent in the range of 10 wt. % or more and less than 50 wt. %, and the flatness of the hole injection layer 20 can be enhanced.

From the viewpoint of preventing volatilization during coating of the inorganic nanoparticle dispersion liquid using an ink-jet method, it is preferable to select a first organic compound and a second organic compound, each having a boiling point of 150° C. or higher and 300° C. or lower, and it is preferable to select a first organic compound and a second organic compound having a boiling point close to each other. From the viewpoint of inhibiting the occurrence of unevenness in the hole injection layer 20, it is preferable to select a combination of a first organic compound and a second organic compound, each having a boiling point of 150° C. or higher and 300° C. or lower, and the difference in boiling point between the first organic compound and the second organic compound of 10° C. or lower. This makes it possible to remove the first organic compound and the second organic compound as much as possible from the film of the inorganic nanoparticle dispersion liquid after coating by heat drying and/or drying under reduced pressure, and to form a flat hole injection layer on the upper face portion 10U and the upper face portion 12U, without losing the balance between the dispersibility of the inorganic nanoparticles by the first organic compound and the wettability with respect to the upper face portion 10U of the anode 10 and the wettability with respect to the upper face portions 12U of the banks 12 by the second organic compound in the film of the inorganic nanoparticle dispersion liquid after coating.

As physical properties suitable for coating by an ink-jet method, the viscosity of the inorganic nanoparticle dispersion liquid is preferably adjusted to be in a range of 4 mPa·s or more and 12 mPa·s or less at 20° C., and the surface tension of the inorganic nanoparticle dispersion liquid is preferably adjusted to be in a range of 25 mN/m or more and 40 mN/m or less.

Here, “wettability” represents the affinity of a liquid for a solid surface. In this aspect, the banks 12 are formed of a material that is more hydrophobic than that of the anode 10. Therefore, by using the first organic compound and the second organic compound in combination as a dispersion medium, the hydrophobicity of the dispersion liquid can be increased by the second organic compound while maintaining the dispersibility of the inorganic nanoparticles by the first organic compound. Therefore, the inorganic nanoparticle dispersion liquid has increased affinity for the upper face portion 10U of the anode 10 and the upper face portions 12U of the banks 12 while maintaining the dispersibility of the inorganic nanoparticles. Due to the first organic compound and the second organic compound, the inorganic nanoparticle dispersion liquid can be expressed as having sufficient dispersibility of the inorganic nanoparticles compatible with wettability to the extent that the dispersion liquid is not repelled at the upper face portion 10U of the anode 10 and the upper face portions 12U of the banks 12.

As described above, the inorganic nanoparticle-containing solution preferably does not contain a surfactant.

In addition, the hole injection layer 20 may be formed to be discontinuous on the banks between pixels by, for example, applying and heating the inorganic nanoparticle-containing solution, and then patterning the thin film of the inorganic nanoparticles through dry etching or wet etching using a photoresist. However, the hole injection layer may be formed without performing the patterning. In this case, the hole injection layer can be conveniently manufactured without causing the manufacturing step to be complicated.

Next, the hole transport layer 22 is formed (step S10). The hole transport layer 22 can be formed by using a method, for example, a coating method using a spin coater, an ink-jet method, or the like. Specifically, for example, the hole transport layer 22 on the banks 12 between pixels may be designed to be discontinuous by applying and heating the solution containing an organic hole transport material, then patterning the thin film of the organic hole transport material through dry etching or wet etching using a photoresist. However, the hole transport layer may be formed without performing the patterning. In this case, the hole transport layer can be conveniently manufactured without causing the manufacturing step to be complicated.

Next, the light-emitting layer 24 is formed (step S12). According to the manufacturing method according to one aspect, the inorganic nanoparticle dispersion liquid inhibits the formation of unevenness caused by aggregation of the inorganic nanoparticles, and the hole injection layer 20 is formed with a uniform film thickness without unevenness. For example, the light-emitting layer 24 can be uniformly formed by using a method, for example, a coating method using a spin coater or an ink-jet method, and in the ink-jet method, the light-emitting layer 24 can be formed with high positional accuracy on the upper face portion 10U of the anode 10 and the upper face portions 12U of the banks 12. The first light-emitting layer of the light-emitting layer 24 can be formed between specific banks 12 by, for example, applying and heating a solution containing a first light-emitting material, and then patterning the thin film containing the first light-emitting material through dry etching or wet etching using a photoresist. Then, a second light-emitting layer and a third light-emitting layer can be formed in the same method as the first light-emitting layer. Here, the light-emitting layer is preferably formed so as to overlap a part of the upper face portions 12U of the banks 12, and thereby, the current flowing through parts other than pixels can be reduced. Furthermore, it is more preferable for the light-emitting layer to be formed in the vicinity of the portion where the height h of the upper face portions 12U of the banks 12 is the highest, and thereby, the current flowing through parts other than the pixels can be further reduced.

Next, the electron transport layer 26 is formed (step S14). The electron transport layer 26 can be formed using any of various conventional methods, for example, vacuum deposition, sputtering, or an application method. Specifically, for example, the electron transport layer 26 on the banks 12 between pixels may be designed to be discontinuous by applying and heating a solution containing an electron transport material, then patterning the thin film of the electron transport material through dry etching or wet etching using a photoresist. However, the hole transport layer may be formed without performing the patterning. In this case, the hole transport layer can be conveniently manufactured without causing the manufacturing step to be complicated.

Next, the cathode 16 is formed (step S16). The cathode 16 can be formed by, for example, forming a thin film of the light reflecting material or the light transmitting material by using a sputtering method, a vacuum deposition method, or the like. Thereby, formation of the light-emitting element 2 is completed.

Next, a sealing layer (not illustrated) is formed (step S18). The sealing layer covers the light-emitting layer and the banks 12 and seals the light-emitting elements. The sealing layer reduces permeation of foreign matter including moisture and the like into the light-emitting layer, the electron transport layer, and the like from outside of the light-emitting elements on the sealing layer side. The sealing layer may have, for example, a layered structure of an inorganic sealing film made of an inorganic material and an organic sealing film made of an organic material.

### Method for Manufacturing Light-Emitting Element 1′

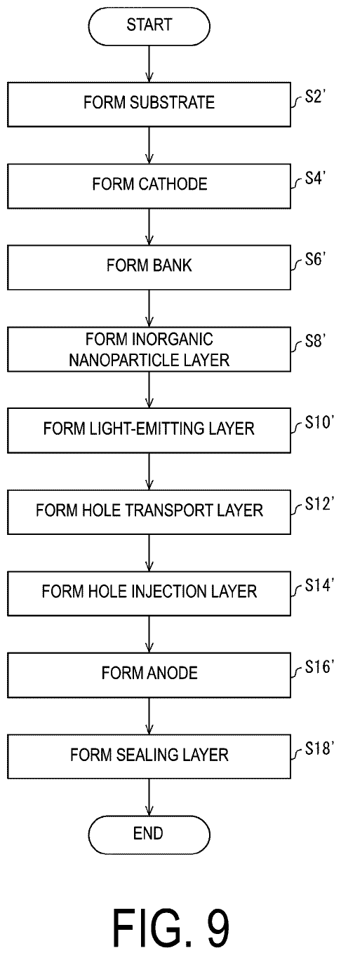

FIG. 9 is a diagram illustrating the schematic flow of an example of the method for manufacturing the light-emitting element 1′ and the layering status in each step. Hereinafter, for convenience of description, steps using the same manufacturing method as that of the light-emitting element 1, but performs in a different order, will be omitted as appropriate.

In the method for manufacturing the light-emitting element according to the present aspect, first, the substrate 4 is formed (step S2′). Next, the cathodes 16 are formed on the substrate 4 (step S4′). The cathodes 16 may be formed by, for example, forming a thin film of a metal material in a sputtering method, a vacuum deposition method, or the like, and then patterning the thin film by dry etching or wet etching using a photoresist. Thus, the cathode 16R, the cathode 16G, and the cathode 16B in island shapes for each subpixel on the substrate 4 can be formed.

Next, after the banks 12 are formed (step S6′), the electron transport layer 26, that is, an inorganic nanoparticle layer, is formed (step S8′). The electron transport layer 26 is formed by, for example, applying an inorganic nanoparticle dispersion liquid by using an ink-jet method or an aerosol jet method and drying the applied dispersion by heating or vacuum drying.

The subsequent steps are, in order, the formation of the light-emitting layer 24 (step S10′), the formation of the hole transport layer 22 (step S12′), the formation of the hole injection layer 20 (step S14′), the formation of the anode (step S16′), and the formation of the sealing layer (not illustrated) (step S18′). The same method as that of the light-emitting element 1 can be employed for each of the steps.

### Action and Effects

According to the configuration and the manufacturing method of the above-described aspects, for example, a light-emitting element having charge function layers (inorganic nanoparticle layers) in which inorganic nanoparticles are sufficiently dispersed and unevenness is inhibited by using the above-described inorganic nanoparticle dispersion liquid is provided. Furthermore, by appropriately adjusting the heating temperature and the degree of vacuum, the first organic compound can be allowed to remain on the surfaces of the inorganic nanoparticles, thus, unevenness resulting from aggregation of the inorganic nanoparticles can be prevented, and the flatness of the charge function layers in the light-emitting element can be improved.

In addition, the display device according to the disclosure includes a plurality of the light-emitting elements, and thus it is possible to improve uneven light emission and enhance reliability.

The disclosure is not limited to the above-described various aspects, various modifications may be made within the scope of the claims, and aspects obtained by appropriately combining technical approaches disclosed in the different aspects also fall within the technical scope of the disclosure. Furthermore, novel technical features can be created by combining the technical approaches disclosed in each aspect.

### EXAMPLE

Hereinafter, each of the above-described aspects will be described in more detail introducing specific examples of the inorganic nanoparticles, the first organic compound, and the second organic compound. The disclosure is not limited to the following examples.

### Example 1

In Example 1, a hole injection layer in a light-emitting element having a normal stacked-layer structure is formed. The hole injection layer in the light-emitting element having a sequential layered structure is formed according to the above-described section <Method for Manufacturing Light-Emitting Element 1> and the flow of FIG. 8.

First, the substrate 4 is formed according to step S2 of FIG. 8. The substrate 4 is formed by, for example, attaching a film base material on a rigid glass substrate having a thickness of 2 mm and a size of 15 cm in width×7 cm, and forming TFTs on the film base material.

Next, anodes are formed on the substrate 4 according to step S4. An Al thin film is formed of a metal material by using a sputtering method, a vacuum deposition method, or the like. Further, an ITO thin film is formed by using a sputtering method, and then the thin film is patterned in dry etching or wet etching using a photoresist. Thereby, the anodes illustrated in FIG. 4 are formed.

Next, the banks in the size range illustrated in FIG. 4 are formed through photolithography using a positive photosensitive resin composition according to step S6. Specifically, the positive photosensitive resin composition serving as a material for the banks is applied onto the upper faces of the anodes formed on the substrate. Next, a photomask having a light-transmitting portion at a position corresponding to each subpixel is placed above the photosensitive resin composition that has been pre-baked after the application, the photosensitive resin composition is irradiated with ultraviolet light or the like through the photomask, and the photosensitive resin irradiated with ultraviolet light is washed with a developing solution. Thereby, the banks surrounding the surfaces of the anodes on the substrate are formed.

Next, the hole injection layer, that is, an inorganic nanoparticle layer made from a hole-injecting material, is formed according to step S8. The hole injection layer may be formed by, for example, applying an inorganic nanoparticle dispersion liquid by an ink-jet method or an aerosol jet method and drying the applied dispersion by heating or vacuum drying.

Examples of the inorganic nanoparticle material used to form the hole injection layer include one or more types selected from the group consisting of oxides, nitrides, and carbides containing one or more of Zn, Cr, Ni, Ti, Nb, Al, Si, Mg, Ta, Hf, Zr, Y, La, Sr, and W. Alternatively, the material is selected from an oxide containing one or more of Zn, Cr, Ni, Ti, Nb, Al, Si, Mg, Ta, Hf, Zr, Y, La, and Sr, NiO, MgO, MgNiO, LaNiO₃ CuO, Cu₂O, CuSCN, and a material in which a CN group, an SCN group, and an SeCN group are bonded to a metal.

As a more specific example, the inorganic nanoparticle dispersion liquid is prepared in the following manner.
1) Nickel oxide nanoparticles are dispersed in ethylene glycol as a first organic compound at a concentration of 10 mg/ml. In the dispersion, stirring is performed with a stirrer, and if necessary, sonication is performed.
2) Subsequently, 1-octanol as the second organic compound is added in an amount of ⅓ vol % relative to the first organic compound described later. Since the dispersibility may be impaired when the second organic compound is added at once, the second organic compound is gradually added by dropping it into the dispersion liquid in which the nickel oxide nanoparticles have been dispersed in the first organic compound while stirring with a stirrer.
3) Finally, the dispersion liquid is caused to pass through a filter with a pore size of 0.45 μm. At this time, the concentration of the nickel oxide nanoparticles is adjusted to about 7.5 mg/ml.

As a more specific example, nickel oxide nanoparticles having a median size of 10 nm or less, which are obtained by autoclaving a liquid obtained by dissolving nickel acetylacetonate (0.35 g) in tert-butanol (35 ml) at 200° C. for 12 to 36 hours, washing the resultant with pure water and ethanol several times, and drying the resultant at 110° C., are used for NiO nanoparticles. (See Organic Electronics 44 (2017) pp. 189-197). Alternatively, nickel oxide nanoparticles commercially available from US Research Nanomaterials, Inc., are employed.

In order to maintain the dispersibility of the inorganic nanoparticles, the content of the second organic compound in the total content of the first organic compound and the second organic compound in the inorganic nanoparticle dispersion liquid is adjusted to 10 wt. % or more and less than 50 wt. %. From the viewpoint of preventing volatilization during coating of the inorganic nanoparticle dispersion liquid using an ink-jet method, a first organic compound and a second organic compound each having a boiling point of 150° C. or higher and 300° C. or lower are selected. Alternatively, in order to inhibit the occurrence of unevenness in the hole injection layer, the first organic compound and the second organic compound each having a boiling point of 150° C. or higher and 300° C. or lower is selected, and a combination of the first organic compound and the second organic compound having the difference in boiling point of 10° C. or lower is selected.

The inorganic nanoparticle dispersion liquid has physical properties suitable for coating by an ink-jet method as described above. Specifically, the viscosity of the inorganic nanoparticle dispersion liquid is adjusted according to a content of the inorganic nanoparticles and a blending ratio of the first organic compound and the second organic compound described below. The viscosity of the inorganic nanoparticle dispersion liquid is adjusted to be within the range of 4 mPa·s or more and 12 mPa·s or less at 20° C. In addition, the surface tension of the inorganic nanoparticle dispersion liquid is adjusted to be within the range of 25 mN/m or more and 40 mN/m or less.

The presence of the first organic compound in the dispersion liquid enables the inorganic nanoparticles to sufficiently disperse and improves the wettability with respect to the anodes. Ethylene glycol is used for the first organic compound. Alternatively, a material is selected from the first organic compounds shown in Table 1 below. In addition, as the first organic compound contained in the inorganic nanoparticle dispersion liquid, a compound having a higher relative dielectric constant than the second organic compound is selected. More specifically, the first organic compound and the second organic compound are selected so that the difference in relative dielectric constant at 20° C. is in the range of 10 or greater and 40 or less.

TABLE 1

| | Relative dielectric | | |
|---|---|---|---|
| | constant (° C., | Surface | Boiling |
| First organic compound | temperatures in | tension | point |
| (First organic solvent) | parentheses) | (mN/m) | (° C.) |
| Ethylene glycol | 37.7 (25) | 43.4 | 198 |
| Propylene glycol | 32.0 (20) | 38 | 187 |
| Diethylene glycol | 31.7(20) | 42.1 | 245 |
| Glycerin | 42.5 (25) | 62 | 290 |
| Dimethyl sulfoxide | 46.7(25) | 43.7 | 189 |
| N,N-dimethylformamide | 36.7 (25) | 25.7 | 153 |
| Formamide | 111 (25) | 32.4 | 211 |
| N-dimethylformamide | 182 (25) | 23.2 | 183 |
| N-methylacetamide | 191 (32) | 30.7 | 206 |
| N.N-dimethylacetamide | 37.8 (25) | 25.4 | 166 |
| N-methyl2-pyrrolidone | 32.3(25) | 33.8 | 202 |

The presence of the second organic compound in the dispersion liquid improves the wettability of the dispersion liquid with respect to the banks. The second organic compound has a relative dielectric constant of 30 or less at 20° C. In addition, the surface tension of the second organic compound is 35 mN/m or less. Specific examples of the second organic compound are shown in Table 2 below.

TABLE 2

| | Relative dielectric | | |
|---|---|---|---|
| | constant (° C., | Surface | Boiling |
| Second organic compound | temperatures in | tension | point |
| (Second organic solvent) | parentheses) | (mN/m) | (° C.) |
| 1-octanol | 10.3 (20) | 29.1 | 195 |
| 1-heptanol | 11.8 (20) | 28.6 | 177 |
| 1-hexanol | 13.0 (20) | 27.9 | 158 |
| Cyclohexanol | 13.4 (25) | 32.5 | 161 |
| Cyclohexane | 16.1 (20) | 32.5 | 156 |
| 2-undecanone | 8.4 (14) | 27.6 | 231 |
| 2-heptanone | 11.9 (20) | 27.9 | 158 |
| Dodecane | 2.0 (20) | 25.6 | 216 |
| Decane | 2.0 (20) | 24.3 | 175 |

As a specific combination of the first organic compound and the second organic compound, [ethylene glycol/1-octanol], [propylene glycol/1-heptanol], [N-methyl-2-pyrrolidone/1-octanol], or [dimethyl sulfoxide+propylene glycol/1-heptanol] is selected from the combinations, and an inorganic nanoparticle dispersion liquid is prepared.

The prepared inorganic nanoparticle dispersion liquid is applied to the substrate on which banks are formed by using an ink-jet method at a discharge amount of 0.1 to 1 ml/cm² per unit area. Thereafter, the inorganic nanoparticle dispersion liquid is dried by heat drying at a temperature in the range of 150 to 250° C. or by vacuum drying under reduced pressure conditions from 10 Pa to 1 kPa. In this manner, the hole injection layer is dried until the content of the first organic compound in the hole injection layer 20 becomes 1000 ppm or less and the content of the second organic compound becomes 100 ppm or less.

Next, the hole transport layer is formed according to step S10 of FIG. 8. The hole transport layer is formed by using a method, for example, a coating method using a spin coater, an ink-jet method, or the like. Specifically, for example, a hole transport layer is generated by applying and dry-heating a solution containing an organic hole transport material.

Then, a light-emitting element is formed according to step S12 to step S18. In the light-emitting element obtained as described above, the difference between at least the mean value of the film thickness distribution of the film thickness D20 and the mean value of the film thickness distribution of D20U of the hole injection layer illustrated in FIG. 6 is 50 nm or less.

### Example 2

In Example 2, an electron transport layer in a light-emitting element having an inverse layered structure is formed. The electron transport layer in the light-emitting element having the inverse layered structure is formed according to the above-described section <Method for Manufacturing Light-Emitting Element 1′> and the flow of FIG. 9.

First, the procedure of forming the substrate 4 according to step S2′ of FIG. 9 and the procedure of forming the banks within the size range illustrated in FIG. 4 by photolithography using a positive photosensitive resin composition according to step S6′ of FIG. 9 are the same as those in Example 1.

Next, cathodes are formed on the substrate according to step S4′ of FIG. 9. An Al thin film is formed of a metal material by using a sputtering method, a vacuum deposition method, or the like. Further, an ITO thin film is formed by using a sputtering method, and then the thin film is patterned in dry etching or wet etching using a photoresist. Thereby, the cathodes illustrated in FIG. 7 are formed.

In order to form the electron transport layer according to step S8′ of FIG. 9, an inorganic nanoparticle dispersion liquid containing inorganic nanoparticles as a material having the electron transport capability is prepared. For inorganic nanoparticles having the electron transport capability, one is selected from oxides containing one or more of Zn, Ni, Cr, Mg, Li, Ti, W, Mo, In, and Ga. Alternatively, for inorganic nanoparticles having the electron transport capability, one is selected from zinc oxide (ZnO), zinc magnesium oxide (MgZnO), titanium oxide (TiO₂), and strontium oxide (SrTiO₃).

As a more specific example, the inorganic nanoparticle dispersion liquid for the electron transport layer is prepared in the following manner.
1) To a solution obtained by dissolving zinc acetate dihydrate (3 mmol) in dimethyl sulfoxide (30 ml), a solution obtained by dissolving tetramethylammonium hydroxide (TMAH, 5 mmol) in ethanol (10 ml) is added, and the resultant is stirred at ambient temperature (about 23° C.) for 1 hour, and the obtained precipitate is washed several times with acetone and ethanol to obtain zinc oxide nanoparticles having a median diameter of about 3 nm (see ACS NANO, vol. 7, No. 8 (2013) pp. 7295-7302).
2) Subsequently, the zinc oxide nanoparticles are dispersed in a first organic compound (N, N-dimethylformamide) at a concentration of 33 mg/ml. At this time, stirring with a stirrer or sonication is performed.
3) Subsequently, a second organic compound (for example, 2-heptanone) is added to the first organic compound so as to be 1/10 vol % (first solvent:second solvent=10:1 (vol:vol)). At this time, 2-heptanone is added dropwise to a solution in which the zinc oxide nanoparticles have been dispersed in the first solvent, while the solution is stirred with a stirrer. Finally, the solution is caused to pass through a filter having a pore size of 0.45 μm to obtain a zinc oxide nanoparticle-containing solution. The concentration of the zinc oxide nanoparticles at this time is adjusted to about 30 mg/ml.

The inorganic nanoparticle dispersion liquid is applied to the substrate on which banks are formed by using an ink-jet method at a discharge amount of 0.1 to 1.0 ml/cm² per unit area. Thereafter, the inorganic nanoparticle dispersion liquid is dried by heat drying at a temperature in the range of 150 to 250° C. or by vacuum drying under reduced pressure conditions from 10 Pa to 1 kPa. In this manner, the electron transport layer is dried until the content of the first organic compound in the electron transport layer becomes 1000 ppm or less and the content of the second organic compound becomes 100 ppm or less.

Next, a light-emitting layer is formed according to step S10′ of FIG. 9. The light-emitting layer is formed by using a method such as a coating method using a spin coater, an ink-jet method, or the like. Specifically, for example, a solution containing a light-emitting material such as quantum dots is applied and dried by heating to form a light-emitting layer.

Then, a light-emitting element is formed according to step S12′ to step S18′. In the light-emitting element obtained as described above, the difference between at least the mean value of the film thickness distribution of the film thickness D26 and the mean value of the film thickness distribution of D26U of the hole injection layer illustrated in FIG. 7 is 50 nm or less.

### REFERENCE SIGNS LIST

1, 1′ Light-emitting element
1R, 1G, 1B Light-emitting element
4 Substrate
10, 10R, 10G, 10B Anode
12 Bank (partition wall)
14R, 14G, 14B, 14R′, 14G′, 14B′ Charge function layer
16, 16R, 16G, 16B Cathode
20 Hole injection layer (charge function layer)
22 Hole transport layer (organic layer, charge function layer)
24, 24R, 24G, 24B Light-emitting layer
26 Electron transport layer (charge function layer)
100 Display device

1. A light-emitting element, comprising:
an anode;
a cathode; and
a light-emitting layer and a charge function layer positioned between the anode and the cathode,
the anode, the cathode, the light-emitting layer, and the charge function layer being layered,
wherein the charge function layer contains inorganic nanoparticles and a first organic compound, and
the first organic compound has a relative dielectric constant of 30 or more at 20° C.

2. The light-emitting element according to claim 1, comprising;
as the charge function layer,
a hole injection layer provided between the anode and the light-emitting layer; and
an organic layer provided between the hole injection layer and the light-emitting layer,
wherein the inorganic nanoparticles have a hole transport capability.

3. The light-emitting element according to claim 1, comprising:
as the charge function layer,
an electron transport layer provided between the cathode and the light-emitting layer,
wherein the inorganic nanoparticles have an electron transport capability.

4. The light-emitting element according to claim 1,
the light-emitting element further comprises a partition wall and a hole transport layer,
wherein the partition wall in contact with at least a part of the anode or the cathode is provided, and
the charge function layer includes a first portion in contact with the light-emitting layer or the hole transport layer and the anode or the cathode and a second portion in contact with the light-emitting layer or the hole transport layer and the partition wall, and a difference between a film thickness distribution of the first portion and a film thickness distribution of the second portion is 50 nm or less.

5. The light-emitting element according to claim 1,
wherein the charge function layer has a film thickness reduction rate of 10% or lower after being immersed in chlorobenzene for 24 hours.

6. The light-emitting element according to claim 1,
wherein the charge function layer further includes a second organic compound, and
a relative dielectric constant of the second organic compound at 20° C. is lower than the relative dielectric constant of the first organic compound at 20° C.

7. The light-emitting element according to claim 6,
wherein the charge function layer contains the first organic compound in a larger amount than the second organic compound.

8. A display device comprising:
a plurality of the light-emitting elements according to claim 1.

9. A method for manufacturing the light-emitting element according to claim 6, the method comprising:
applying an inorganic nanoparticle dispersion liquid containing the inorganic nanoparticles, and further the first organic compound and the second organic compound, onto one or both of the anode or the cathode and the light-emitting layer, and drying the inorganic nanoparticle dispersion liquid, forming a charge function layer containing the inorganic nanoparticles.

10. The method for manufacturing the light-emitting element according to claim 9,
wherein the second organic compound has a relative dielectric constant of less than 30 at 20° C.

11. The method for manufacturing the light-emitting element according to claim 9,
wherein a difference between the relative dielectric constant of the first organic compound at 20° C. and the relative dielectric constant of the second organic compound at 20° C. is 10 or greater.

12. The method for manufacturing the light-emitting element according to claim 9,
wherein a content of the second organic compound with respect to a sum of the first organic compound and the second organic compound is within a range of 10 mass % or more and 50 mass % or less.

13. The method for manufacturing the light-emitting element according to claim 9,
wherein a surface tension of the second organic compound is 35 mN/m or less.

14. The method for manufacturing the light-emitting element according to claim 9,
wherein a difference in boiling point between the first organic compound and the second organic compound is 10° C. or less.

15. The method for manufacturing the light-emitting element according to claim 9,
wherein the first organic compound and the second organic compound each have a boiling point between 150° C. and 300° C.

16. (canceled)

17. The method for manufacturing the light-emitting element according to claim 9,
wherein the inorganic nanoparticles include one or more types selected from the group consisting of an oxide, a nitride, and a carbide containing one or more of Zn, Cr, Ni, Ti, Nb, Al, Si, Mg, Ta, Hf, Zr, Y, La, Sr, W, and Cu.

18. The method for manufacturing the light-emitting element according to claim 17,
wherein the inorganic nanoparticles are inorganic nanoparticles made from nickel oxide.

19. The method for manufacturing the light-emitting element according to claim 9,
wherein the inorganic nanoparticle dispersion liquid has a viscosity in a range of 4 mPa·s or more and 12 mPa·s or less.

20. The method for manufacturing the light-emitting element according to claim 9,
wherein the inorganic nanoparticle dispersion liquid has a surface tension in a range of 25 mN/m or more and 40 mN/m or less.

21. (canceled)

22. A light-emitting element, comprising:
an anode;
a cathode; and
a light-emitting layer and a charge function layer positioned between the anode and the cathode,
the anode, the cathode, the light-emitting layer, and the charge function layer being layered,
wherein the charge function layer contains inorganic nanoparticles and a first organic compound,
the first organic compound has a relative dielectric constant of 30 or more at 20° C.,
the charge function layer further includes a second organic compound,
a relative dielectric constant of the second organic compound at 20° C. is lower than the relative dielectric constant of the first organic compound at 20° C., and
a difference in boiling point between the first organic compound and the second organic compound is 10° C. or less.
